(19) United States
(12) Patent Application Publication
(10) Pub. No.: US 2007/0070737 A1
(43) Pub. Date: Mar. 29, 2007

(54) METHOD AND AUXILIARY DEVICE FOR CREATING AND CHECKING THE CIRCUIT DIAGRAM FOR A CIRCUIT WHICH IS TO BE INTEGRATED

(76) Inventor: Horst Fischer, Raubling (DE)

Correspondence Address: PATTERSON & SHERIDAN, LLP;Gero McClellan / Infineon / Qimonda, 3040 POST OAK BLVD.,, SUITE 1500, HOUSTON, TX, 77056, US

(21) Appl. No.: 11/535,011

(22) Filed: Sep. 25, 2006

(30) Foreign Application Priority Data
Sep. 24, 2005 (DE) DE 102005045716.9

(51) Int. Cl. G11C 29/00

(52) U.S. Cl. 365/200

(57) ABSTRACT

Method and apparatus for creating and checking a circuit diagram for a circuit which is to be integrated. On the basis of this circuit diagram, a layout for the circuit which is to be integrated is designed. Both when designing the circuit diagram and in a layout description extracted from the designed layout, the sections of connecting lines within the line networks are defined by structure parameter values which prescribe the length and width of the line sections and also specify the impedance-determining layer properties of the conductor layer which is to be produced when integrating the respective line section. Individual line networks in the layout are then compared with the corresponding networks in the circuit diagram by comparing the indicated structure parameter values.

### CROSS-REFERENCE TO RELATED APPLICATIONS

This application claims foreign priority benefits under 35 U.S.C. §119 to co-pending German patent application number DE 10 2005 045 716.9, filed 24 Sep. 2005. This related patent application is herein incorporated by reference in its entirety.

### BACKGROUND OF THE INVENTION

1. Field of the Invention

The invention relates to a method for creating and checking the circuit diagram for an electrical circuit which is to be integrated. The invention also relates to an auxiliary device for carrying out the method.

2. Description of the Related Art

The design of integrated circuits using what is known as the full custom method, particularly the design of very large scale integration (VLSI) circuits using this method, normally starts with the graphical design of a circuit diagram which contains the circuit elements and their electrical connections and is usually drawn by the circuit designer on a computer screen. For each circuit element drawn in such circuit diagrams (also called “schematics”), an identifier is used which identifies the element in question and which allows the function of the element in question to be comprehended sufficiently accurately. To take account of the parasitic capacitances C, resistances R and inductances L of the lines connecting the circuit elements, which likewise influence the response of the circuit, it is known practice to draw these line parasitics as discrete C, R and L elements with estimated values in the circuit diagram, likewise with identifiers which identify these elements and define their estimated values.

The circuit diagram designed in this way is usually transferred together with the identifiers for the elements to a computer in order to be able to check the electrical response of the circuit by means of computer simulation. On the basis of this check, the circuit designer can establish whether and/or to what extent his choice of circuit elements and their connections to one another could produce a circuit with the desired function. If necessary, the circuit designer can modify the circuit diagram on the accordingly programmed computer interactively (so to speak “manually”) until the simulation shows the desired result. Normally, the description or virtual map of the circuit diagram in the computer has a hierarchic structure. This means that the overall circuit is divided into blocks which each independently form a functional unit, with a respective plurality of blocks on a hierarchy level being combined to form a block on the next highest hierarchy level. It is thus possible to check single parts of the circuit independently in each case, specifically step by step from the bottommost to the topmost hierarchy level. With blocks of the same kind, a single check on just one of these blocks suffices, and any modification made can easily be copied to the other blocks.

To implement the designed circuit (that is to say the circuit described by the circuit diagram) as an integrated circuit on a semiconductor chip, a “layout” needs to be developed from the circuit diagram, i.e. a description of the geometry and of the spatial arrangement of the circuit components on the chip. This layout defines the patterns of the masks which are to be used in the lithographic production of the integrated circuit. The circuit diagram is usually transformed into a suitable layout graphically by the layout designer on a screen (that is to say likewise manually), and this may also at least partially be done automatically; various programs are known for computer-aided (and also interactive) layout creation. The layout is also given a hierarchic structure.

Certain constraints need to be observed in the layout, known as “layout rules”, which are dependent, inter alia, on the production technology and on the rated operation values for current, voltage and frequency in the circuit which is to be integrated. The observance of these rules can be monitored automatically in the course of layout creation, for which purpose there are likewise suitable computer programs (e.g., Design Rule Check or DRC programs).

When designing the layout for the connecting lines, the line parasitics drawn in the circuit diagram are normally ignored, which means that there is relatively great design freedom for the geometry of the connecting lines. This relates to the physical course of the lines, their dimensions and also the topology of the individual line networks. The term “line network” here means the set of all directly interconnected line sections, with the topology relating to the internal split of branches or nodes within the line network and also to the locations of any abrupt changes in the line properties. Said design freedom is limited only by the aforementioned layout rules in this case. As regards the circuit elements themselves, there is usually only little or no design freedom, since their layout is usually standardized, i.e. stipulated from the outset by the identifier which has been input when designing the circuit diagram.

The next step to take place is a “layout-based” function check, i.e. a check is performed to determine whether and/or to what extent the circuit would be able to perform the function desired by the circuit designer if it were integrated on the basis of the designed layout. To this end, the line parasitics for all sections of each network of connecting lines are ascertained (“extracted”) from the geometric and material-describing data of the layout. This parasitics extraction (known as RCL extraction) is normally performed using suitable software tools. The function of the circuit described by the circuit diagram is then checked by computer simulation, with the extracted parasitics being taken as a basis instead of the previously estimated line parasitics. This “post-layout simulation” is used to achieve significantly more realistic simulation results.

The post-layout simulation often reveals that the estimated line parasitics previously drawn in the circuit diagram are far removed from the reality of the later layout, and the results of the earlier “pre-layout simulation” on the basis of the circuit diagram differ significantly from the post-layout simulation results. Original assumptions about the performance of the circuit can prove to be false and in many cases necessitate complex changes in a later phase of the project.

It is therefore desirable to estimate the line parasitics in the circuit diagram as precisely as possible before the layout creation. To this end, the line parasitics extracted from the layout which has already been created can be taken as a model, so to speak, in order to state more precisely the parasitics estimation at least for designing other circuits which have a similar function and are probably given a similar layout. It is thus known practice to compare the estimated line parasitics drawn in the circuit diagrams for such similar circuits with the extracted line parasitics of the model and to align them if required.

Software tools for automatically comparing the circuit diagrams with the layout are known, but line parasitics have not been included to date in this context, essentially for the following reasons:
(a) automated comparison requires accurate 1:1 mapping of the extracted line parasitics from the layout onto the circuit diagram. Such mapping would result in the circuit diagrams being overloaded with the parasitic elements and would make these diagrams unreadable for creating the layout.
(b) circuit diagrams and layout normally have a hierarchic structure, with the hierarchy of the circuit diagrams not necessarily being identical to the hierarchy of the layout, however. Hence, by way of example, circuits which appear in the same manner in the circuit diagram may have different layout implementations and hence also different line parasitics.
(c) the previously granted design freedom for the layout means that the topology of a line network in the circuit diagram does not necessarily match that of the layout. For this reason, exact 1:1 mapping of the extracted line parasitics from the layout onto the circuit diagram is not always possible.

Hence, the comparison of the extracted line parasitics with the estimated line parasitics entered in the circuit diagram and the alignment of said parasitics has to date had to be done in complex fashion by an experienced circuit designer who compares the topology and the line parasitics of each line network described in the layout with the topology described in the circuit diagram and with the line parasitics of the relevant line network by inspection and uses the observed differences to estimate what changes he needs to make manually in the circuit diagram in order to achieve the best possible alignment with the model. Allowing for the fact that, in particular, very large scale integrated circuits contain several hundred thousand or even millions of line networks, it can be seen that the complexity for a complete inspection comparison of all networks and the subsequent manual corrections would exceed any sensible measure.

### SUMMARY OF THE INVENTION

According to a first aspect of the invention, a method is provided for creating and checking the circuit diagram for an electrical circuit which is to be integrated. A circuit diagram for the circuit which is to be integrated is designed and, on the basis of this circuit diagram, a layout for the circuit which is to be integrated is designed and features of this layout design are compared with features of the circuit diagram. Both when designing the circuit diagram and in a layout description extracted from the designed layout, the sections of connecting lines within the line networks are defined by structure parameter values which prescribe the length and width of the line sections and also specify the impedance-determining layer properties of the conductor layer which is to be produced when integrating the respective line section. Individual line networks in the layout are compared with the corresponding networks in the circuit diagram by comparing the indicated structure parameter values.

According to a second aspect of the invention, an auxiliary device for creating and checking the circuit diagram for an electrical circuit which is to be integrated, wherein a circuit diagram for the circuit which is to be integrated is designed and, on the basis of this circuit diagram, a layout for the circuit which is to be integrated is designed and features of this layout design are compared with features of the circuit diagram, has a first input device for inputting the data from the circuit diagram into a first database and a second input device for inputting the data from the layout into a second database. The first input device is designed to input the data from line networks as structure parameter values which indicate the length and the width of the line sections in the respective network and also indicate the impedance-determining layer properties of the conductor layer which is to be produced when integrating the respective line section. The second database has an associated extraction device which takes the layout's data contained in this database and extracts therefrom the data from the line networks in the layout as structure parameter values which indicate the length and the width of the line sections in the layout of the respective network and also indicate the impedance-determining layer properties of the conductor layer. A comparison device is provided for comparing individual line networks' structure parameter values which have been input into the first database with the relevant line networks' structure parameter values which have been extracted from the data in the second database.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 shows a flowchart which illustrates the steps of an embodiment of an inventive method.

FIG. 2 shows an inventive circuit diagram representation of a simple line network.

FIG. 3 shows a first variant of the layout for the network shown in FIG. 1.

FIG. 4 shows a second variant of the layout for the network shown in FIG. 1.

FIG. 5 shows the description extracted in line with the invention for the layout shown in FIG. 4.

FIG. 6 shows a third variant of the layout for the network shown in FIG. 1.

FIG. 7 shows the description extracted in line with the invention for the layout shown in FIG. 6.

### DETAILED DESCRIPTION OF THE PREFERRED EMBODIMENT

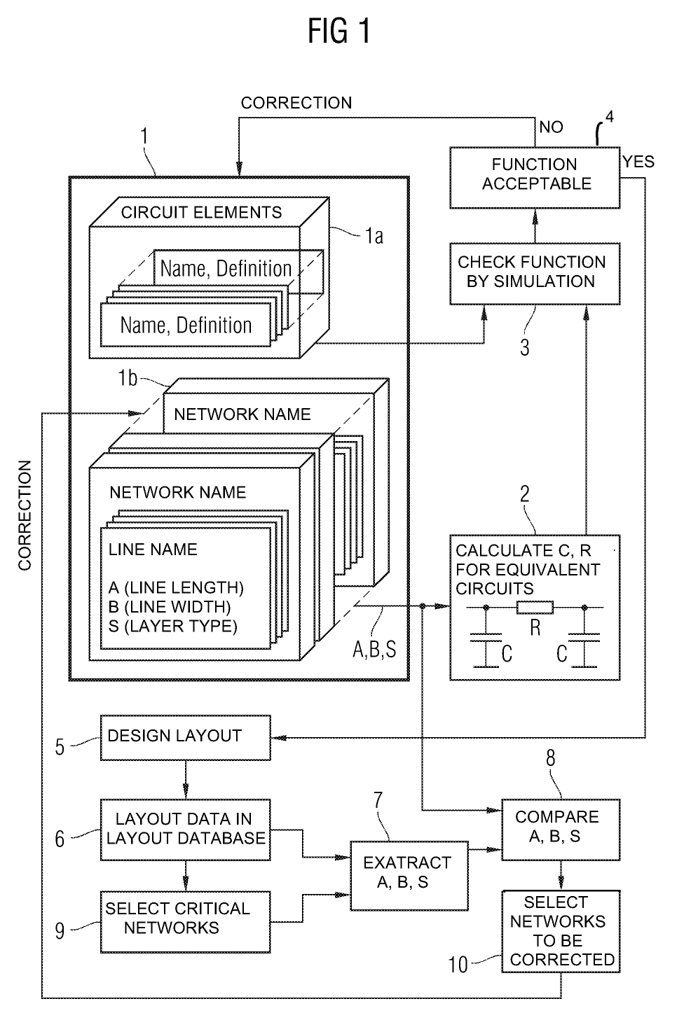

FIG. 1 shows the constituent parts or steps of the method using numbered blocks containing inscriptions. In FIG. 1, the method starts by designing a circuit diagram (block 1) on a computer screen, with all circuit elements and all line sections which connect individual circuit nodes or connections of the circuit elements to one another being respectively provided with a name for identification and with an identifier for definition. The circuit nodes and connections are likewise allocated names. In addition, each line network (subsequently also referred to as “network” for short), that is to say each group of directly interconnected line sections, is allocated its own name to identify it.

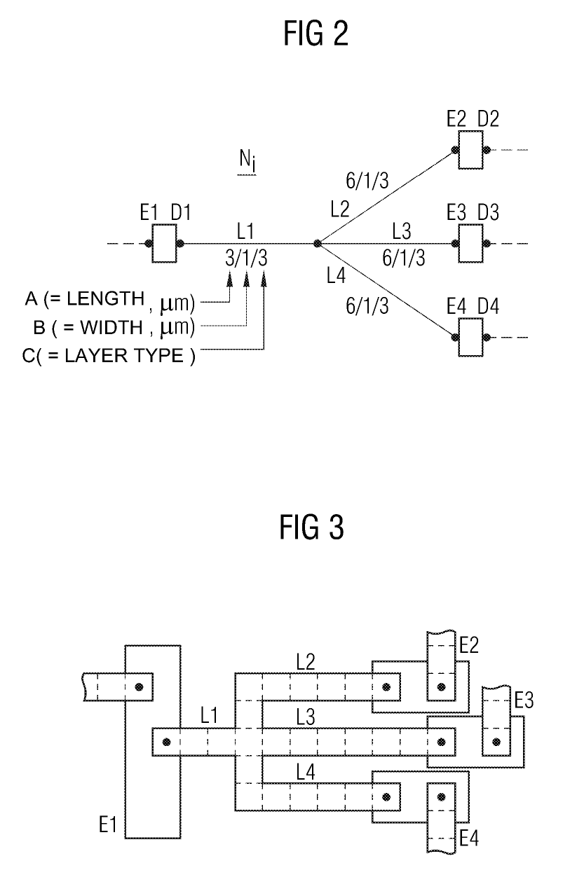

FIG. 2 shows an example of part of the circuit diagram which comprises a relatively simple network connecting the output of a signal source provided with the name E1 to the inputs of three signal sinks (names E2, E3, E4). The four elements E1:4 may be situated in the same or in different hierarchy level(s) within an extensive overall circuit (not shown). Besides the names E1:4, the circuit diagram also contains the identifiers D1:4 (e.g. the type descriptors) for defining the elements in question.

The network shown in FIG. 2, provided with the network name Nᵢ, comprises a first line section with the name L1 which is routed from an output connection of the element E1 to a node, where three line sections with the names L2, L3, L4 branch off to the input connections of the three elements E2, E3, E4. Nodes and connections are symbolized by black dots, their names not being shown in the figure for reasons of clarity.

As mentioned above, one particular feature of the invention is that the line sections within the networks are defined by indicating structure parameter values from which it is possible to calculate the line parasitics. In the example shown, there are three structure parameters, namely the length A of the line section, its width B and a parameter S indicating specific properties of the conductor layer which is to be produced when the respective line section is integrated.

All data for the overall circuit diagram are stored in a “schematics” database. The database permits targeted access to the data from individual networks (using the network name) and to the data from individual line sections of the respective network (using the “line name”). This access option is illustrated schematically in section 1b of the block 1 in FIG. 1. In addition, the Schematics database permits the network data to be linked to the data from the circuit elements (shown symbolically in section 1a of block 1) such that the circuit described in the circuit diagram can have its function checked by simulation if desired (block 3 in the flowchart shown in FIG. 1). This simulation considers each line section as a passive equivalent circuit with at least one capacitive parallel impedance and with at least one resistive or resistive and inductive series impedance, the impedances being ascertained from the structure parameter statements in the circuit diagram (step 2).

In one embodiment, the equivalent circuit used for each line section is a pi circuit, comprising two parallel capacitances and a series resistor arranged in between, as illustrated within block 2 in FIG. 1. If A is the length and B is the width of the line section (e.g. respectively measured in μm), then in this “pi model” a value of the series resistance is
R=R_{S}*A/B, eq.1,
where R_{S} (in ohms per square unit area) is the layer resistance of the connecting line, which is dependent on the specific resistance of the conductor material and on the conductor thickness. For the value of each of the two parallel capacitances, the following is obtained
C=[(C_{F}*A*B)+(2C_{R}*(A+B))]/2 eq.2,
where C_{F} (in pF/μm²) is the capacitance per unit area and C_{R} (in pF/μm) is the fringing capacitance of the line relative to the substrate.

The values of R_{S}, C_{F} and C_{R} belong to the “layer properties” of the line sections and are determined by the “type” of the material layer which forms a line section in the integrated circuit which is to be produced. The layer type for its part is determined by the process parameters which are to be applied during lithographical integration of the respective layer on a semiconductor chip. Each layer type is linked to a particular selection of conductor material and conductor thickness (and hence layer resistance R_{S}) and to particular predictable values of C_{F} and C_{R}. It thus suffices to introduce a parameter “layer type” S, naming a particular combination of values for R_{S}, C_{F} and C_{R}, in the description of the circuit diagrams for the line networks in addition to the geometric parameters “length” A and width “B”. In one embodiment, a directory is set up, for example, in the form of a lookup table which indicates the relevant combination of values for the layer properties for each of a plurality of selectable layer types.

The equivalent circuit described above does not take into account of the influences of any line inductances. In most practical cases, the inductances are actually negligibly small. However, should it be supposed that they have a significant influence on the function of the overall circuit, then the equivalent circuit needs to be provided with a suitably proportioned inductance in series with the series resistance. The value L of this equivalent inductance is likewise determined by the structure parameters and can likewise be extracted from the circuit diagram. In one embodiment, only the length of the relevant line section is taken into account in this context, because this length is the dominant factor for the inductance value. Any other factors such as couplings to the environment can generally be ignored, as can the physical course of the line.

Instead of a pi circuit, a different form of equivalent circuit may also be designed, e.g., a “T” circuit with two series impedances and a parallel capacitance which branches off in between, or a “semi-T” circuit with a single series impedance and a single parallel capacitance. Corresponding models naturally require somewhat different proportioning of the equivalent circuit elements than described above. A more detailed explanation in this regard can be dispensed with, since a person skilled in the art will readily be able to derive the relevant proportioning specification for any type of equivalent circuit from the structure parameters of the line section in question.

On the basis of the result of the simulation (block 3 in FIG. 1), a decision is made (block 4) as to whether the circuit described in the circuit diagram (block 1) functions in the desired manner. If not, the circuit designer can make corrections to the circuit diagram and can request a fresh simulation. The “correction loop” via blocks 1, 2, 3, 4 can be executed a plurality of times until the circuit described by the circuit diagram can be considered to be working (“yes” decision at block 4).

The next step to come is the design of the layout (block 5) using the stipulations from the circuit diagram. This layout can be drawn by the layout designer on a computer screen. During layout design for the line networks, the layout designer is meant to keep to the structure parameter values A, B, S prescribed in the circuit diagram as far as possible. He has a free choice for the design of the physical course of the respective lines, however. In this regard, the layout designer usually describes all the line sections as polygons. For the circuit elements, the layout designer can use standardized patterns on the basis of the elements' identifiers indicated in the circuit diagram. The data from the layout designed are stored in a Layout database, as symbolized by block 6 in the flowchart shown in FIG. 1.

FIG. 3 shows a layout for the network N1 shown in FIG. 2, which layout would meet the stipulations in the circuit diagram in terms of length, width and layer type of the line sections exactly. In practice, however, the situation may arise that this exact match is not always obtained. The layout designer may either make unintentional errors or may be forced for various reasons to depart from the structure stipulations of the circuit diagram. One such reason may be, by way of example, that a line network in the layout needs to be in a different hierarchy level than in the circuit diagram. Such departures may relate to single values of the structure parameters prescribed by the circuit diagram and/or even the topology of the line network. Another reason may be that the result of the layout rule check (DRC) turns out to be negative and requires a modification.

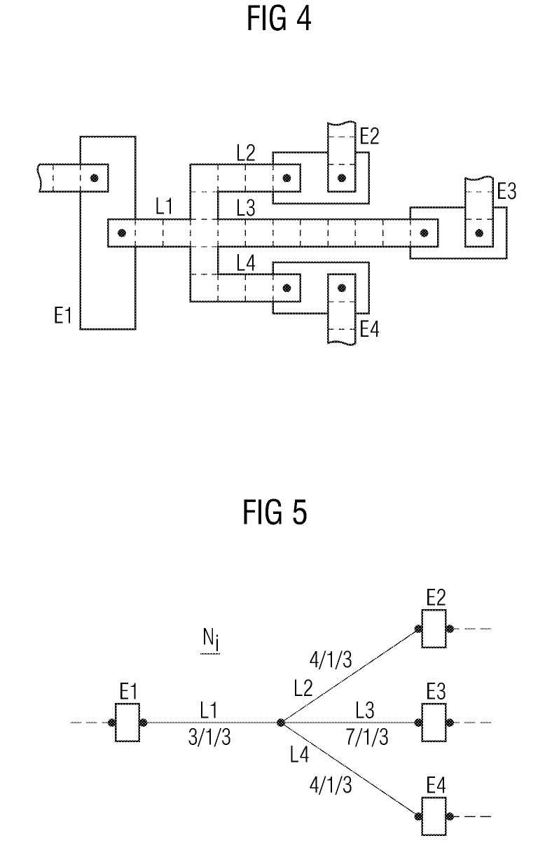

In the case of the layout shown in FIG. 3, the automatic layout rule check could result in the physical spacing between the elements E2, E3, E4 being too small, for example. As a remedial measure, the layout designer could then alter the layout of the network Nᵢ in the manner shown by FIG. 4. In this case, the stipulations of the circuit diagram regarding network topology and regarding line section L1 continue to be met, but the lengths of the line sections L2, L3, L4 now differ from these stipulations. Alternatively, enforced changes in the line width B or in the layer type S are conceivable and not ruled out in practice.

For the purposes of comparison between the layout of a network and the stipulations contained in the circuit diagram, a layout description is extracted from the layout data stored in the Layout database (block 7 in FIG. 1), said layout description explicitly indicating, for the line sections of the network, the values applicable in the layout for the structure parameters A (length), B (width) and S (layer type), that is to say the same parameters as were taken as a basis for the description of the circuit diagram. Extracting these structure parameter values is far less complex than the previously customary and computationally more complicated extraction of capacitance, inductance and resistance values from the layout data.

For the layout shown in FIG. 3, the layout description extracted in this manner corresponds to the circuit diagram shown in FIG. 2. The extracted layout description for the “differing” layout shown in FIG. 4 is shown in FIG. 5.

The comparison itself (block 8 in FIG. 1) respectively contains, for each line network, only the comparison of two groups of values, namely the comparison of the values indicated in the circuit diagram for the parameters A, B, S (from block 1) with the values of these parameters which are indicated in the extracted layout description (from block 7). This comparison can be effected automatically and very quickly, which means that the total number of all comparison operations requires only a little time, even for a very large number of line networks, as can be found in very large scale integrated circuits.

If the layout follows the stipulations of the circuit diagram exactly, the comparison will show a match, that is to say will signal that the real layout can be used for the line network in question. The circuit diagram can therefore remain unchanged.

The comparison described provides a simple way of quickly and automatically identifying all the line networks in which the layout differs from the stipulations of the circuit diagram. The “differing” line networks form a subset of the total set of all line networks. The structure stipulations of the circuit diagram and the restricted design freedom of the layout designer mean that this subset will make up only a fraction of the total set. Interactive manual correction of the circuit diagram therefore needs to relate only to this fraction, which significantly reduces the time involvement.

The complexity can be reduced further if a selection from the large number of available networks is actually made before the comparison. This is because only the really “critical” line networks whose line parasitics have a certain minimum influence on the overall circuit are of interest in principle. Hence, in one advantageous refinement of the invention, measures can be taken to select the critical line networks on the basis of the layout data stored in the Layout database (block 9 in FIG. 1). Various criteria may be used in this context. In one embodiment, the networks which are selected are the networks whose electrical response is dominated by parasitic capacitance and the networks whose electrical response is dominated by parasitic resistance.

A “capacitance-dominated” network exists when the capacitance of the network seen in isolation (that is to say the sum of the line capacitances of all the line sections in the network in question) is relatively high in relation to the total capacitance, which additionally contains the connection capacitances of all the circuit elements attached to the network. In one embodiment, all networks in which said ratio exceeds a selected threshold value are therefore selected. This threshold value may be a value based on general experience. It has been found that a value in the range between 10% and 30% is suitable, a preferable value being at or close to 20%. A similar criterion may also be prescribed for the inductances if the inductive response of the network plays a significant role at all; in most practical instances, the inductances are negligible, however.

A “resistance-dominated” network exists when the ratio of the sum of the resistances of all the line sections in the network to the internal resistance of the signal source supplying the network is relatively high. In one embodiment, all networks in which said resistance ratio exceeds a selected threshold value are therefore selected. This threshold value may also be a value based on general experience. It has been found in this case that a value in the range between 30% and 100% is suitable, a preferable value being at or close to 50%.

The described selection of the critical networks can likewise easily be automated. All said threshold values can be based on general experience, as mentioned, or can be found empirically in advance, e.g. by means of simulation using a model which represents a relatively simple line network. The described selection of the line networks reduces the complexity for correction by a considerable measure in addition.

On the basis of the comparison results from block 8, a decision can be made regarding which networks require correction in the circuit diagram (block 10 in FIG. 1). Not all identifiable differences will actually require corrective measures. It is thus possible to select only those networks for corrective measures in which the ascertained difference are large enough to alter the electrical properties of the line network in question to an extent which significantly affects the overall circuit. An experienced circuit designer can gage this when considering the comparison result. Alternatively, the decision can be automated, e.g. by means of automatic threshold comparison. Thus, one particular refinement of the invention may involve a line network being selected for correction only if the difference between individual structure parameter values for the layout and the values indicated in the circuit diagram is greater than a respective preselected threshold value. This difference can be expressed, by way of example, by the absolute value of the difference between the compared parameter values or by the ratio of the respective higher value to the lower value.

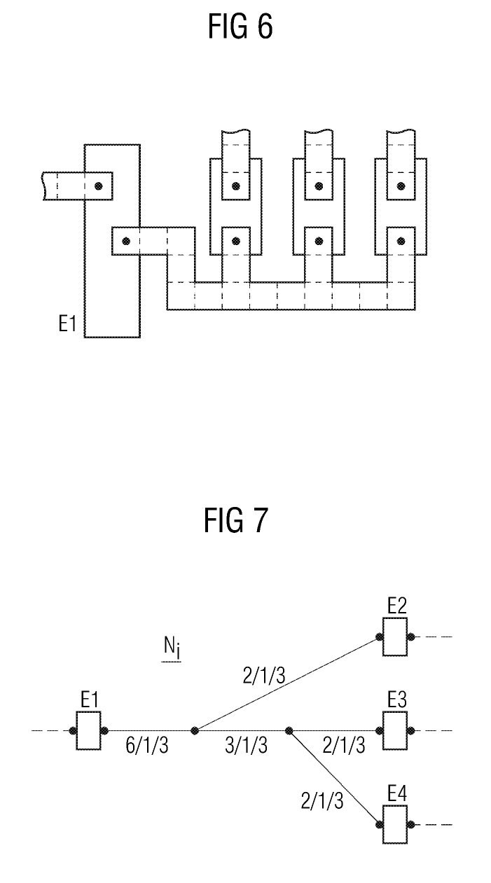

Line networks which have been provided with a different topology in the layout than in the circuit diagram are not accessible to a direct comparison (in block 8) of the structure parameter values of individual line sections. FIG. 6 shows an example of how a layout for the network Nᵢ described in the circuit diagram shown in FIG. 1 might result in a change in the network topology. FIG. 7 shows the layout description extracted from the data for this layout. An attempted comparison between this layout description and the circuit diagram for the network will fail, which may prompt the automatic comparison system to send an appropriate report. Such line networks reported as “incomparable” must naturally likewise be selected for corrective measures.

Correction involves aligning the structure parameter values in the circuit diagram for each line network selected as requiring correction with the relevant values for the layout. This is symbolized in FIG. 1 by the arrow pointing from block 10 to block 1a. The alignment can be made manually (“interactively”) by the circuit designer by virtue of his entering the values which can be taken from the extracted layout description (block 7) into the circuit diagram. Once the topology has been changed, a circuit diagram description of the new topology is required. The features of the new topology can be identified visually by the circuit designer from a graphical illustration of the extracted layout description of the relevant line network.

The circuit described by the corrected circuit diagram can have its function checked by simulation in the same way as was described above for the function check for the circuit diagram. Should this reveal unacceptable functional weaknesses or errors then the layout needs to be changed.

Parts of the inventive method can be carried out using parts of an auxiliary device, e.g. using suitable electronic processing circuits and data stores. The auxiliary device can be implemented through appropriate equipment and programming of computers. For stipulation of the structure parameter values of the network line sections in the Schematics database by the circuit designer (block 1a in FIG. 1) and for input of the layout data into the Layout database by the layout designer (block 6), respective suitable devices on a design or layout computer can be used, e.g. the keyboard and individual fields to be filled in using said keyboard in an appropriately configured form on the computer screen.

To extract the layout description indicating the structure parameter values of these network line sections (block 7 in FIG. 1) and to compare these structure parameter values with the values indicated in the circuit diagram (block 8), the auxiliary device may contain an appropriately designed computing device, e.g. implemented by an appropriate program for the arithmetic and logic unit of a computer. Suitable computing devices and computing programs also allow other parts to be implemented in the auxiliary device, namely a device for selecting the critical networks (block 9 in FIG. 1), an evaluation device for selecting the networks to be corrected (block 10), a device for calculating the components of the line parasitics equivalent circuit (block 2) and a device for the simulated function check (block 4).

The invention specifies a technique for creating and checking the circuit diagram for a circuit which is to be integrated where comparison of the line networks described in the circuit diagram with the line networks in the designed layout can be automated.

Accordingly a method for creating and checking the layout for integrating an electrical circuit designs a circuit diagram for the circuit which is to be integrated and, on the basis of this circuit diagram, a layout for the circuit which is to be integrated and compares features of this layout design with features of the designed circuit diagram. Both when designing the circuit diagram and in a layout description extracted from the designed layout, the sections of connecting lines within the line networks are defined by structure parameter values which prescribe the length and width of the line sections and also specify the impedance-determining layer properties of the conductor layer which is to be produced when integrating the respective line section. Individual line networks in the layout are then compared with the corresponding networks in the circuit diagram by comparing the indicated structure parameter values.

The line networks are defined in the actual circuit diagram in a manner which provides specifications for designing the layout which are more precise than the specifications by a circuit diagram described in conventional fashion. Although this may restrict the design freedom for layout creation somewhat, it has significant advantages on the other hand.

A fundamental advantage is that the circuit diagram and the extracted layout description define the line networks using the same parameter groups, namely those which describe the physical-structural features, these groups forming table templates, so to speak, which contain the values of the relevant parameters as entries. It is therefore very simple to compare the line networks described in the circuit diagram with the line networks described by the real layout.

The preceding description only describes advantageous exemplary embodiments of the invention. The features disclosed therein and the claims and the drawings can, therefore, be essential for the realization of the invention in its various embodiments, both individually and in any combination. While the foregoing is directed to embodiments of the present invention, other and further embodiments of this invention may be devised without departing from the basic scope of the invention, the scope of the present invention being determined by the claims that follow.

What is claimed is:

1. A method for creating and checking a circuit diagram for an electrical circuit which is to be integrated, comprising:
designing the circuit diagram for the electrical circuit which is to be integrated;
designing, based on the circuit diagram, a layout for the electrical circuit which is to be integrated;
extracting a layout description from the designed layout; and
comparing features of the layout are compared with features of the circuit diagram,
wherein both when designing the circuit diagram and in the layout description extracted from the designed layout, sections of connecting lines within one or more line networks are defined by structure parameter values which prescribe lengths and widths of the sections of connecting lines and specify impedance-determining layer properties of a respective conductor layer which is to be produced when integrating a respective line section, and
wherein individual line networks in the layout are compared with corresponding networks in the circuit diagram by comparing respective indicated structure parameter values.

2. The method of claim 1, wherein, based on data from the designed layout, only those line networks whose capacitive and resistive properties influence a response of the electrical circuit beyond a preselected measure are selected for the comparison.

3. The method of claim 2, wherein all of those networks in which a ratio of a sum of respective line capacitances of all the line sections to a total capacitance, which additionally contains connection capacitances of all circuit elements attached to the respective network, exceeds a selected threshold value are selected for the comparison.

4. The method of claim 2, wherein all those networks in which a ratio of a sum of respective resistances of all the line sections in the network to an internal resistance of a signal source supplying the network exceeds a selected threshold value are selected for the comparison.

5. The method of claims 1, further comprising correcting the circuit diagram by aligning the structure parameter values prescribed therein for the line networks with the structure parameter values indicated in the extracted layout description of the designed layout.

6. The method of claim 5, wherein the structure parameter values are aligned by replacing the structure parameter values prescribed in the circuit diagram with the structure parameter values indicated in the extracted layout description only in those line networks in which a difference in individual values exceeds a preselected value.

7. The method of claim 1, wherein, when designing the circuit diagram, a function of the electrical circuit described therein is checked by simulation, with each line section being handled as a passive equivalent circuit with at least one capacitive parallel impedance and with at one resistive or resistive and inductive series impedance, the impedances being ascertained from the indicated structure parameter values.

8. The method of claim 5, wherein a function of the electrical circuit described in the corrected circuit diagram is checked by simulation, with each line section being handled as a passive equivalent circuit with at least one capacitive parallel impedance and with at least one resistive or resistive and inductive series impedance, the impedances being ascertained from the structure parameter values indicated in the corrected circuit diagram.

9. The method of claim 1, wherein a statement of layer properties of the line sections includes the statement of a layer resistance value R_{S}, of a capacitance per unit area value C_{F} and of a fringing capacitance value C_{R} of the conductor layer.

10. The method of claim 9, wherein each equivalent circuit is defined as a pi circuit in which a series impedance comprises a nonreactive resistance having the value
R=R_{S}*A/B
and each parallel capacitance has the value
C=[(C_{F}*A*B)+(2C_{R}*(A+B))]/2,
wherein A is the length and B is the width of the respective line section.

11. The method of claim 1, wherein the layer properties are indicated by naming one of a plurality of possible layer types whose respective layer properties are stored in a directory and can be retrieved by indicating the respective name.

12. An auxiliary device for creating and checking the circuit diagram for an electrical circuit which is to be integrated, wherein a circuit diagram for the circuit which is to be integrated is designed and, on the basis of this circuit diagram, a layout for the circuit which is to be integrated is designed and features of this layout design are compared with features of the circuit diagram, comprising:
a first input device for inputting data from the circuit diagram into a first database and a second input device for inputting data from the layout into a second database,
wherein the first input device is designed to input the data from line networks as structure parameter values which indicate lengths and widths of line sections in a respective network and indicate impedance-determining layer properties of a conductor layer which is to be produced when integrating a respective line section, and
wherein the second database has an associated extraction device which takes the layout's data contained in this database and extracts therefrom the data from the line networks in the layout as structure parameter values which indicate the lengths and the widths of the line sections in the layout of the respective network and indicate the impedance-determining layer properties of the conductor layer; and
a comparison device for comparing individual line networks' structure parameter values which have been input into the first database with relevant line networks' structure parameter values which have been extracted from the data in the second database.

13. The auxiliary device of claim 12, further comprising a selection device which is connected upstream of the comparison device and which takes the layout data which have been input into the second database as a basis for selecting for comparison only those line networks whose capacitive and resistive properties influence the response of the circuit beyond a preselected value.

14. The auxiliary device of claim 13, wherein the selection device selects for comparison all those networks in which a ratio of a sum of line capacitances of all line sections to a total capacitance, which additionally contains connection capacitances of all circuit elements attached to the network, exceeds a selected threshold value.

15. The auxiliary device of claim 13, wherein the selection device selects for comparison all those networks in which a ratio of a sum of resistances of all line sections in the network to an internal resistance of a signal source supplying the network exceeds a selected threshold value.

16. The auxiliary device of claim 12, further comprising a simulation device for simulating a function of the circuit described by the circuit diagram, the simulation device comprising a computing device which takes the line sections' structure parameter values which have been input into the first database and calculates components of a passive equivalent circuit with at least one capacitive parallel impedance and with at least one resistive or resistive and inductive series impedance.

17. The auxiliary device of claims 12, wherein the structure parameter values which define the layer properties of the line sections define the layer resistance value R_{S}, the capacitance per unit area value C_{F} and the fringing capacitance value C_{R} of the conductor layer.

18. The auxiliary device of claims 16, wherein each equivalent circuit is a pi circuit in which a series impedance is a nonreactive resistance having the value
R=R_{S}*A/B
and each parallel capacitance has the value
C=[(C_{F}*A*B)+(2C_{R}*(A+B))]/2,
wherein A is the length and B is the width of the respective line section.

19. The auxiliary device of claim 12, further comprising a directory of selectable conductor layer types for integrating lines in which the respective layer properties are stored for each of these layer types as a data record, and wherein the first input device is designed to input a layer type name for retrieving the data record which indicates a respective relevant layer properties from the directory.

20. The auxiliary device of claim 12, further comprising an evaluation device which is connected downstream of the comparison device and which takes the comparison result as a basis for reporting whether differences which have been established exceed a threshold value.
